(19) United States
(12) Patent Application Publication
(10) Pub. No.: US 2025/0114953 A1
(43) Pub. Date: Apr. 10, 2025

(54) TRANSFER ARM

(71) Applicant: Helios Technical Services, LLC, Cave Creek, AZ (US)

(72) Inventors: Mike Halpin, Cave Creek, AZ (US); Steve Burch, Scottsdale, AZ (US)

(21) Appl. No.: 18/907,266

(22) Filed: Oct. 4, 2024

Related U.S. Application Data
(60) Provisional application No. 63/542,459, filed on Oct. 4, 2023.

(51) Int. Cl. B25J 18/00; B25J 11/00; B25J 15/06; B25J 19/00

(52) U.S. Cl. CPC B25J 18/00; B25J 11/0095; B25J 15/0616; B25J 19/0075

(57) ABSTRACT

The present invention is a transfer arm that moves a wafer inside a piece of equipment designed to manufacture electronic circuits. The transfer arm has a hand, used to securely hold the wafer using Bernoulli's Principle. The transfer arm has a left wrist and a right wrist connected to the hand, wherein the hand and the left wrist and the right wrist comprise sealed gears and sealed bearings. A left upper arm is connected by being threaded to the left wrist and a left elbow and a right upper arm is connected by being threaded to the right wrist and a right elbow. A left lower arm is connected by being threaded to the left elbow and the left shoulder and a right lower arm is connected by being threaded to the right elbow and the right shoulder.

### CROSS-REFERENCE TO RELATED APPLICATIONS

This application claims the benefit of U.S. Provisional Application No. 63/542,459, filed on Oct. 4, 2023, the contents of which is incorporated herein by reference in its entirety.

### FIELD OF THE INVENTION

The present invention relates to a transfer arm for transporting a wafer inside a piece of equipment used during the manufacturing process of semiconductors such as computer chips.

### BACKGROUND

Computer chips often control the electronic devices that we use and rely on every day. Everything from modern cars, smart cell phones, gaming consoles, lap top computers and medical equipment, use computer chips. The power and versatility of computer chips is only likely to grow in the future.

Computer chips are most often manufactured on semiconductor silicon wafers. The manufacturing process requires hundreds of steps and can take weeks to complete. The wafers are typically stored and transported to various pieces of equipment in a wafer cassette carrier. The wafers must be transported to and from different pieces of equipment for processing in a particular sequence.

Once the wafers have been loaded onto a piece of equipment for processing, an automated wafer handling system may be designed to automate and facilitate the handling of silicon wafers during the manufacturing process of computer chips in the piece of equipment.

### SUMMARY OF THE INVENTION

Accordingly, the invention is directed to a system to facilitate the moving of a wafer inside of or to a piece of equipment that is used to manufacture semiconductor devices, such as computer chips.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

Embodiments of the present invention include a transfer arm that may be incorporated into a wafer handling device configured to move a wafer inside or to a piece of equipment designed to manufacture computer chips. The transfer arm may include a wafer transfer hand which, in preferred embodiments, uses the Bernoulli's Principle to hold the wafer.

A left wrist and a right wrist may be connected to the hand. The hand and the left wrist and the right wrist may incorporate sealed gears and sealed bearings. The sealed gears of the left wrist and the right wrist with the hand are hidden from a line of sight of the wafer during the manufacture of computer chips to prevent any contaminants from reaching the computer chips. In addition, the sealed bearings are sealed from any corrosive process gasses during the manufacture of the computer chips to prevent corrosion of the sealed bearings.

A left upper arm may be connected to the left wrist and a right upper arm may be connected to the right wrist by a left wrist threaded section and a right wrist threaded section respectively. A left elbow may be connected to the left upper arm and a right elbow may be connected to the right upper arm by a left upper elbow threaded section and a right upper elbow threaded section respectively.

A left lower arm may be connected to the left elbow and a right lower arm may be connected to the right elbow by a left lower elbow threaded section and a right lower elbow threaded section respectively. A left shoulder may be connected to the left lower arm and a right shoulder may be connected to the right lower arm by a left shoulder threaded section and a right shoulder threaded section respectively.

This Summary section is neither intended to be, nor should be, construed as being representative of the full extent and scope of the present disclosure. Additional benefits, features and embodiments of the present disclosure are set forth in the attached figures and in the description hereinbelow, and as described by the claims. Accordingly, it should be understood that this Summary section may not contain all of the aspects and embodiments claimed herein.

Additionally, the disclosure herein is not meant to be limiting or restrictive in any manner. Moreover, the present disclosure is intended to provide an understanding to those of ordinary skill in the art of one or more representative embodiments supporting the claims. Thus, it is important that the claims be regarded as having a scope including constructions of various features of the present disclosure insofar as they do not depart from the scope of the methods and apparatuses consistent with the present disclosure (including the originally filed claims). Moreover, the present disclosure is intended to encompass and include obvious improvements and modifications of the present disclosure.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a perspective view of a transfer arm according to an embodiment of the invention;

FIG. 2 is a left side vertical cross-sectional view of the transfer arm;

FIG. 3 is a left side vertical cross-sectional view of a hand and a shoulder of the transfer arm;

FIG. 4 is a left side vertical cross-sectional view of an elbow of the transfer arm;

FIG. 5 is a left side vertical cross-sectional perspective view of the transfer arm;

FIG. 6 is a left side vertical cross-sectional view of the hand of the transfer arm;

FIG. 7 is an exposed top plan view inside the hand and wrists of the transfer arm;

FIG. 8 is a bottom view of a protective cover over the hand and wrists of the transfer arm;

FIG. 9 is an exposed bottom view inside the hand showing the sealed bearings and sealed gears; and

FIG. 10 illustrates a top view of a frame for the hand of the transfer arm.

### DETAILED DESCRIPTION OF THE ILLUSTRATED EMBODIMENTS

The following detailed description describes a transfer arm, method of using and making the same and is presented to enable any person skilled in the art to make and use the disclosed subject matter in the context of one or more particular implementations. Various modifications, alterations, and permutations of the disclosed implementations can be made and will be readily apparent to those skilled in the art, and the general principles defined may be applied to other implementations and applications, without departing from scope of the disclosure. The present disclosure is not intended to be limited to the described or illustrated implementations, but to be accorded the widest scope consistent with the described principles and features.

For the purposes of promoting an understanding of the principles of the present disclosure, reference will now be made to the exemplary embodiments illustrated in the drawing(s), and specific language will be used to describe the same.

Appearances of the phrases an “embodiment,” an “example,” or similar language in this specification may, but do not necessarily, refer to the same embodiment, to different embodiments, or to one or more of the figures. The features, functions, and the like described herein are considered to be able to be combined in whole or in part one with another as the claims and/or art may direct, either directly or indirectly, implicitly or explicitly.

As used herein, “comprising,” “including,” “containing,” “is,” “are,” “characterized by,” and grammatical equivalents thereof are inclusive or open-ended terms that do not exclude additional unrecited elements or method steps unless explicitly stated otherwise.

Computer chips are now ubiquitous in our society. Computer chips are necessary to operate our modern cars (often having thousands of computer chips per car), cell phones, computers, Internet and even modern household appliances like refrigerators and washing machines. Societies reliance on computer chips is only growing as we develop the Internet of Things (IoT), virtual reality products, artificial intelligence (AI), high speed communication systems and deep learning. It is safe to say that computer chips are critical to our future technological development.

The manufacturing process for computer chips starts with a salami-shaped bar of silicon. High-speed saws slice the ingot into wafers. Depending on the use, the wafers may be of different thicknesses and diameters. As an example of a common size, wafers may be about 0.4 mm to 0.5 mm thick and with a diameter of about 300 mm, although smaller diameter wafers are also common. In the future, 450 mm diameters wafers may become more common. Hundreds of processors or thousands of computer ships may be created from a single wafer.

The manufacturing process to create computer chips on a wafer often involves hundreds of steps and months of processing time. Typical steps include photolithography, doping the wafer, deposition processes, photoresist deposition, chemical mechanical polishing (CMP), etching, cleaning, electroplating and layering interconnects.

The wafers are typically stored and transported between processes in a wafer cassette carrier. Each piece of equipment to process the wafers typically has a place to load an input wafer cassette carrier with the wafers to be processed and another place for an output wafer cassette carrier to hold the wafers once the wafers have been processes by the piece of equipment. In some pieces of equipment, the input wafer cassette carrier may also be used as the output wafer cassette carrier. Each piece of equipment, depending on the particular process they are performing, typically needs to move the wafers from the input wafer cassette carrier to a processing station and then after completing the process, move the wafers to the output wafer cassette carrier. The movement of the wafers to and from the wafer cassette carriers and through the piece of equipment is an important aspect of the process performed by an automated wafer handling system.

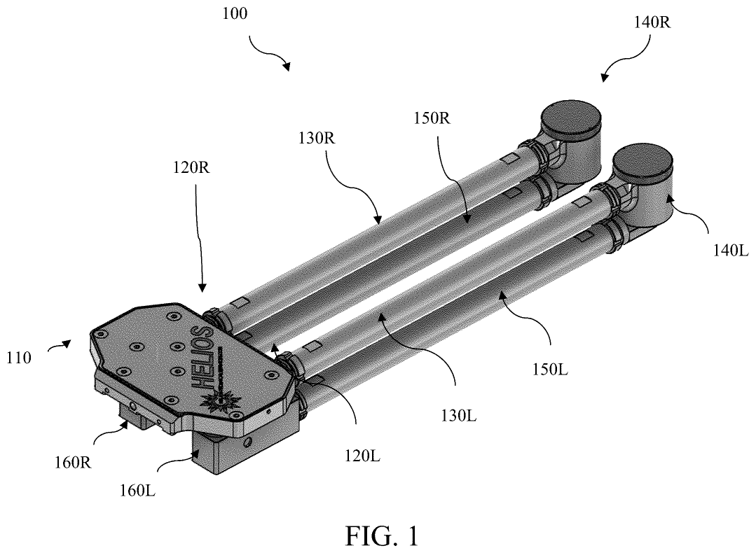

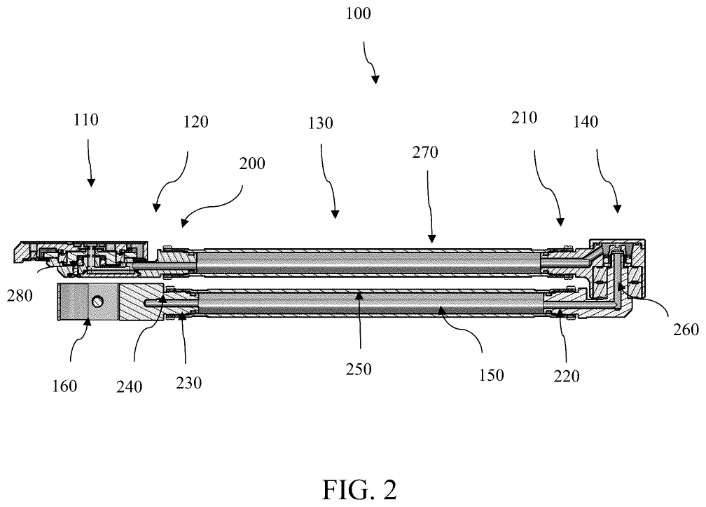

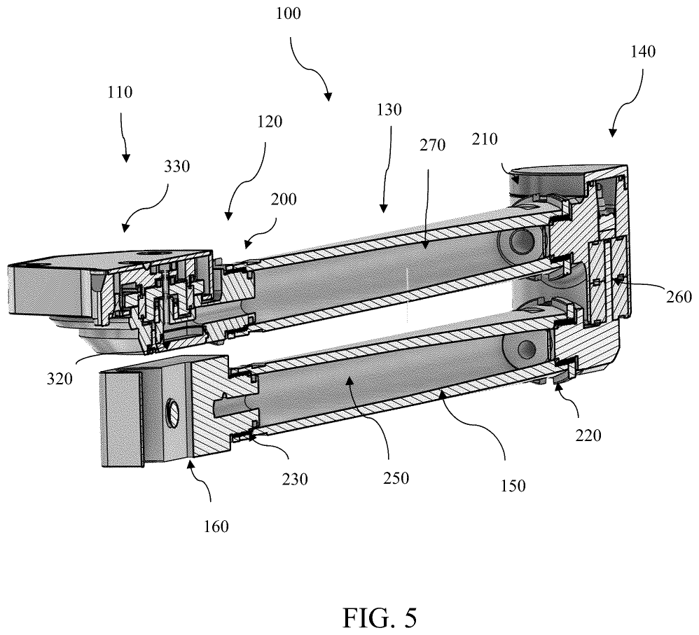

An automated wafer handling system may be robotic systems designed to automate and facilitate the handling of silicon wafers during the various semiconductor manufacturing processes. Wafer handlers are typically integrated with the semiconductor processing equipment which perform various manufacturing tasks throughout the semiconductor production lifecycle. Referring to FIGS. 1-9, an automated wafer handling systems may have a robotic arm, hereinafter a transfer arm 100, to load and unload wafer cassette carriers.

The importance of cleanliness in handling and moving the wafers cannot be overstated. Particles that are far too small for the human eye to see can still easily destroy computer chips during their manufacturing process and greatly reduce their manufacturing yield rate (number of accepted computer chips vs the total number of computer chips made). Compounding the problem is that semiconductor processing equipment often uses highly corrosive gasses and/or liquids as part of their process. Exposed bearings or gears may experience high rates of corrosion which could introduce unacceptable contaminates into the manufacturing process environment. What is needed is an automated wafer handling system, and in particular a transfer arm 100, that is easy to clean, mitigates the creation of particles and reduces the possible sources of contaminates in the computer chip manufacturing environment.

Reference will now be made in detail to an embodiment of the present invention, examples of which are illustrated in the accompanying drawings. FIGS. 1, 2 and 5 illustrate a possible embodiment of a transfer arm 100 according to the present invention which may be used as part of an automated wafer handling system for a piece of equipment used to manufacture computer chips on wafers. The transfer arm 100 may have a hand 110 that is used to hold a wafer when the transfer arm 100 is moving the wafer to or from a wafer cassette carrier or to or from a processing station. The hand 110 may hold the wafer using any desired method.

In a preferred embodiment, the hand 110 holds a wafer using Bernoulli's principle. For the hand 110 to use Bernoulli's principle to hold the wafer, the wafer handling station must receive or have a source of compressed gas. The compressed gas may be released inside the transfer arm 100 at the shoulders 160L and 160R and exit through ports in the hand 110 to allow the hand 110 to hold the wafer using Bernoulli's principle. This requires the transfer arm 100 to have an airtight passageway for the gas to travel from the shoulders 160L and 160R all the way through the transfer arm 100 to exit ports in the hand 110. Specifically, the compressed gas must flow through airtight interconnected chambers within the shoulders 160L and 160R to the lower arms 150L and 150R to the elbows 140L and 140R to the upper arms 130L and 130R to the wrists 120L and 120R and finally to the exit ports in the hand 110. The transfer arm 100 must be airtight while also being able to move and rotate at least at the shoulders 160L and 160R, elbows 140L and 140R and wrists 120L and 120R.

The airtight interconnected chambers within the transfer arm 100, even though only passing a clean gas, will still build up undesired particles and contaminants over time. This buildup of particles and contaminants may eventually be released under pressure through the ports in the hand 110, thereby contaminating the processing of the wafer. It is thus important that the transfer arm 100 be easily taken apart and cleaned.

Bernoulli's principle states that within a horizontal flow of fluid, points of higher fluid speed will have less pressure than points of lower fluid speed. The transfer arm 100 may be supplied with a steady flow of a gas (such as clean air or clean N₂) that flows out of the hand 110 at a plurality of gas outlets at a velocity towards a bottom surface of the wafer. The gas flows around the bottom surface of the wafer at a higher fluid speed than the gas at an upper surface of the wafer. This causes a pressure differential between the bottom surface and the upper surface of the wafer. The pressure differential is specifically a low-pressure area between the hand 110 and under the wafer and a high-pressure area above the wafer. This pressure differential effectively holds the bottom surface of the wafer to the hand 110, but without the hand 110 physically touching the wafer which could otherwise create undesired particles or even damage the wafer. In this manner, the wafer may be held by the hand 110 with the wafer either above or below the hand 110.

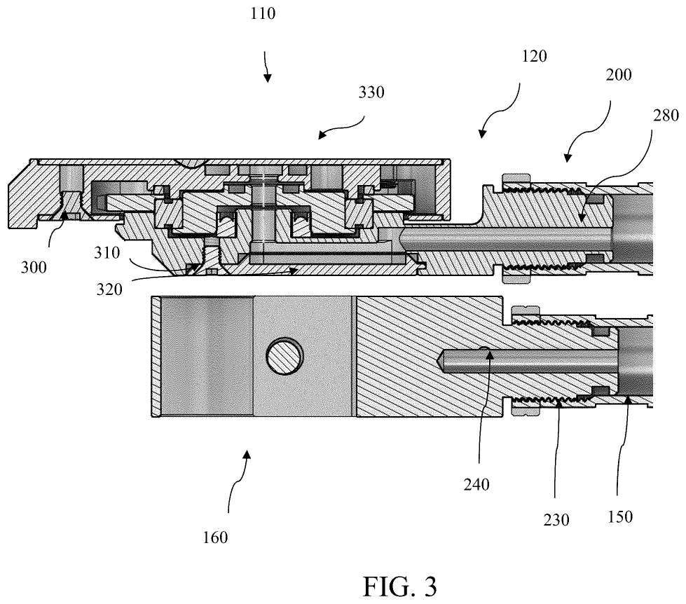

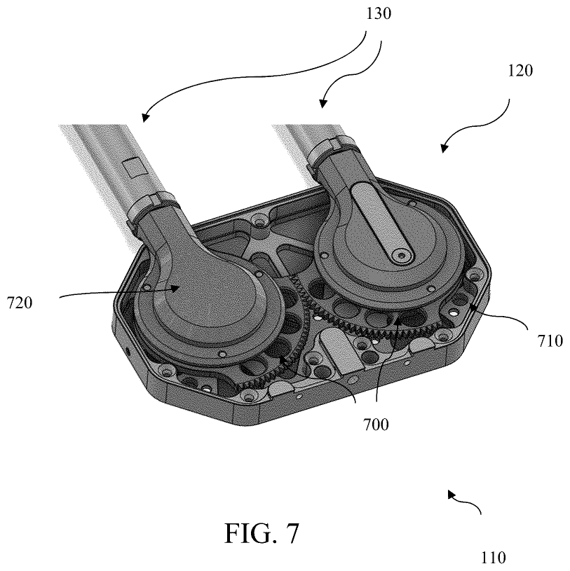

FIGS. 3 and 7 show an enhance view of how the hand 110 is connected to two wrists 120 (a left wrist 120L and a right wrist 120R) of the transfer arm 100 via bearings 720 and gears 700 in the hand 110. FIG. 7 illustrates how the bearings 720 in the hand 110 may be completely sealed, i.e., sealed bearings 720, to prevent particles created in the bearings 720 during movement of the transfer arm 100 from escaping the hand 110 and wrists 120 and entering the computer chip processing areas. An O-ring 710 may be placed along an outer edge of the hand 110 to further seal the gears 700 in the hand 110, i.e., sealed gears 700.

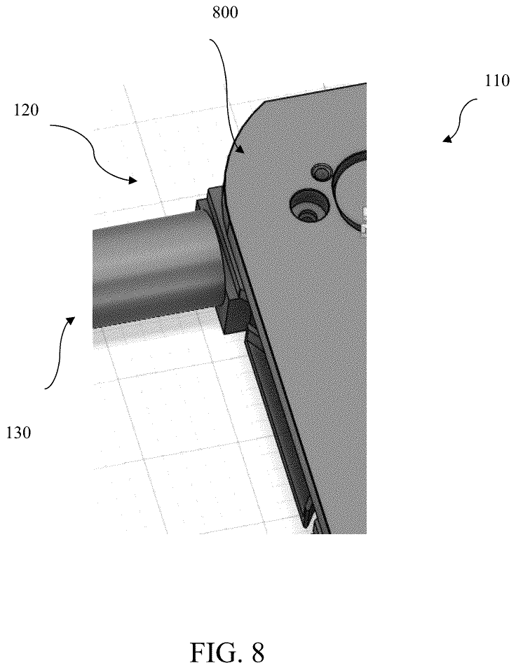

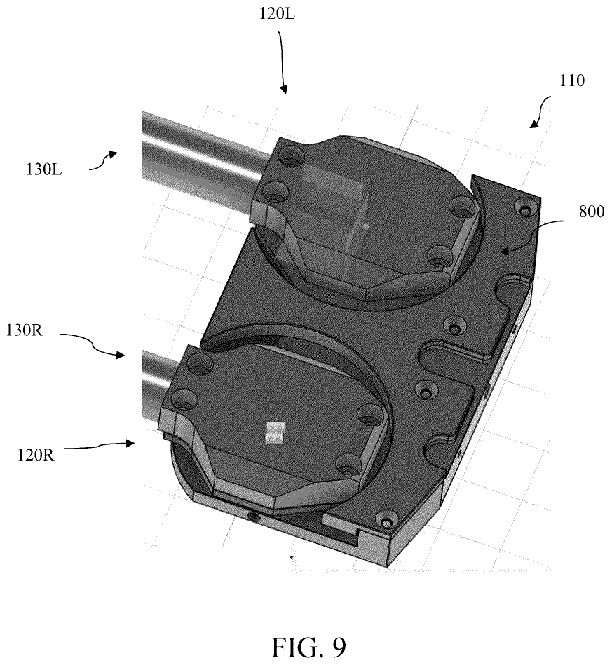

FIGS. 8 and 9 illustrate a cover 800 that can be used to seal and fully enclose the gears 700 in combination with the O-ring 710 illustrated in FIG. 7. Sealing and enclosing the bearings 720 and the gears 700 in the hand 110 and wrists 120 not only prevents corrosive agents from reaching the bearings 720 and the gears 700, which could greatly reduce their useful lifetime and create additional contaminates, but the cover 800 also creates a barrier that prevents contaminates created by the bearings 720 and gears 700 from escaping the hand 110 and wrists 120 and reaching the computer chip processing areas.

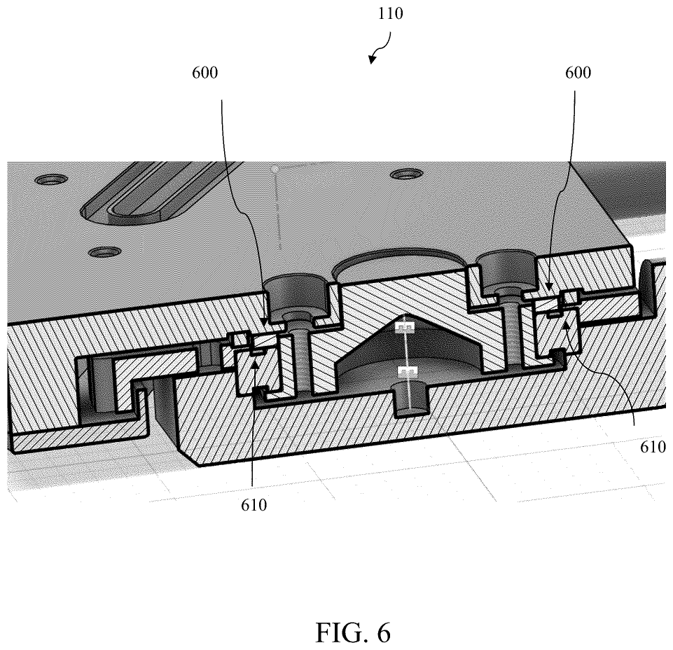

FIG. 6 illustrates a portion of the transfer arm 100 that comprises the wrists 120 and hand 110. The wrists 120 and hand 110 include a seal 600 that may be made of any desired material. In a preferred embodiment, the seal 600 is made of a compressible material such as rubber and is most preferably made of polytetrafluoroethylene (PTFE). The seal 600 helps to further protect the wafer from the bearings 610 in the hand 110 and wrists 120 and to protect the bearings 610 from the process gasses used in the piece of equipment to manufacture computer chips. The seal 600 does this by trapping any contaminates inside the hand 110 and wrists 120, thereby preventing the contaminates inside the hand 110 and wrists 120 from entering the computer chip/semiconductor processing area.

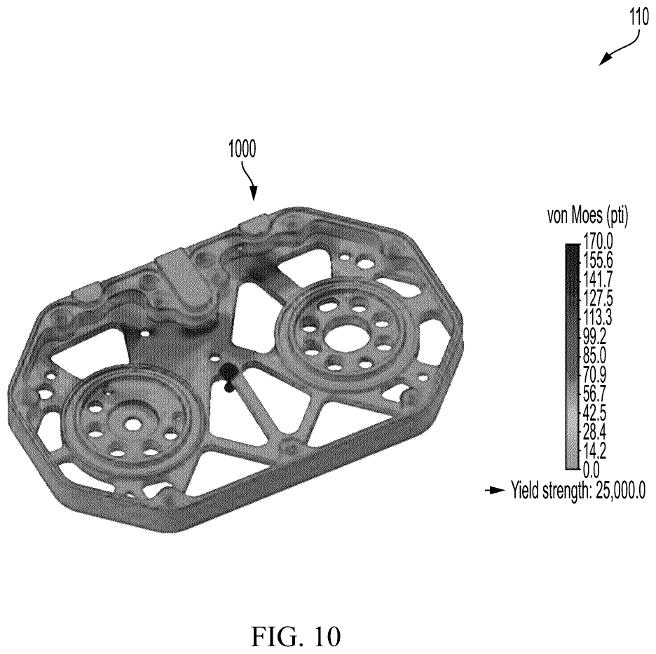

FIG. 10 illustrates a frame 1000 upon which the parts of the hand 110 and wrists 120 may be mounted. The frame 1000 is preferably light, but strong. The frame 1000 may have a plurality of disassembly points that allow for the easy disassembly, cleaning and reassembly of the hand 110 and wrists 120 components.

FIG. 3 illustrates an upper hand screw 300, out of a plurality of not shown upper hand screws 300, that allows an upper plate 330 of the hand 110 to be removed that allows an upper portion of the hand 110 to be easily cleaned. FIG. 3 also illustrates a lower hand screw 310, out of a plurality of not shown lower hand screws 310, that allows a lower plate 320 in the hand 110 to be removed that allow a lower portion of the hand 110 to be easily cleaned. The upper hand screws 300 and lower hand screws 310 may be any desired means of attaching an upper plat and a lower plate 320 to the hand. As non-limiting examples, the upper hand screws 300 and lower hand screws 310 may be latches, clasps, magnets, screws or bolts.

The sealed gears of the left wrist 120L and the right wrist 120R with the hand 110 are hidden from a line of sight of the wafer during the manufacture of computer chips to prevent any contaminants from reaching the computer chips. In addition, the sealed bearings 720 are sealed from any corrosive process gasses during the manufacture of the computer chips to prevent corrosion of the sealed bearings 720.

Referring again to FIGS. 1, 2 and 5, the right wrist 120R is connected to a right upper arm 130R and the left wrist 120L is connected to a left upper arm 130L. The wrists 120 and the upper arms 130 may be connected by any desired means, such as by welding (not preferred). However, as a preferred non-limiting example, the wrists 120 and upper arms 130 may be connected by a wrist threaded section 200. FIG. 3 illustrates an embodiment where the wrists 120 have bolt like threads (outside threads), while the upper arms 130 have nut like threads. In another embodiment, the wrists 120 have nut like threads (inside threads), while the upper arms 130 have bolt like threads (outside threads). The wrist threaded sections 200 allow the wrists 120 to be removed from their corresponding upper arms 130 to allow for the easy cleaning of both the wrists 120 and the upper arms 130.

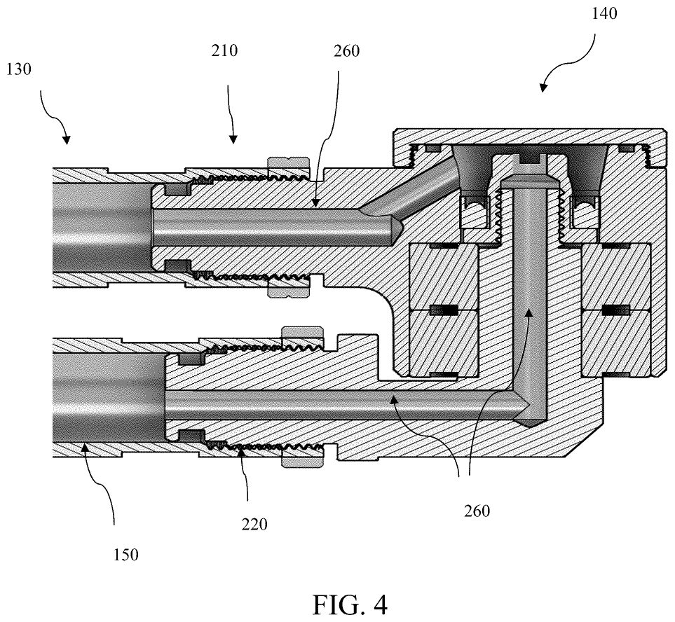

Referring to FIGS. 1, 2 and 4, the right upper arm 130R is connected to a right elbow 140R and the left upper arm 130L is connected to a left elbow 140L. The upper arms 130 and elbows 140 may be connected by any desired means, such as by wielding (not preferred). However, as a preferred non-limiting example, the upper arms 130 and the elbows 140 may be connected by an upper elbow threaded section 210. FIG. 4 illustrates an embodiment where the upper arms 130 have nut like threads (inside threads), while the elbows 140 have bolt like threads (outside threads). In another embodiment, the upper arms 130 have nut like threads (inside threads), while the elbows 140 have bolt like threads (outside threads). The upper elbow threaded sections 210 allow the upper arms 130 to be removed from their corresponding elbows 140 to allow for the easy cleaning of both the upper arms 130 and the elbows 140.

Referring to FIGS. 1, 2 and 4, the right elbow 140R is connected to a right lower arm 150R and the left elbow 140L is connected to a left lower arm 150L. The elbows 140 and lower arms 150 may be connected by any desired means, such as by wielding (not preferred). However, as a preferred non-limiting example, the elbows 140 and lower arms 150 may be connected by a lower elbow threaded section 220. FIG. 4 illustrates an embodiment where the elbows 140 have bolt like threads (outside threads), while the lower arms have nut like threads (inside threads). In another embodiment, the elbows 140 have nut like threads (inside threads), while the lower arms 150 have bolt like threads (outside threads). The lower elbow threaded sections 220 allow the elbows 140 to be removed from their corresponding lower arms 150 to allow for the easy cleaning of both the elbows 140 and the lower arms 150.

Referring to FIGS. 1, 2, 3 and 5, the right lower arm 150R is connected to a right shoulder 160R and the left lower arm 150L is connected to a left shoulder 160L. The lower arms 150 and shoulders 160 may be connected by any desired means, such as by wielding (not preferred). However, as a preferred non-limiting example, the lower arms 150 and shoulders 160 may be connected by a shoulder threaded section 230. FIG. 3 illustrates an embodiment where the lower arms 150 have nut like threads (inside threads), while the shoulders 160 have bolt like threads (outside threads). In another embodiment, the lower arms 150 have bolt like threads (outside threads), while the shoulders have nut like threads (inside threads). The shoulder threaded sections 230 allow the lower arms 150 to be removed from their corresponding shoulders 160 to allow for the easy cleaning of both the lower arms 150 and the shoulders 160.

In a preferred embodiment, the left upper arm 130L, right upper arm 130R, left elbow 140L, right elbow 140R, left lower arm 150L, right lower arm 150R, left shoulder 160L and right shoulder 160R are easily disconnected from each other and the transfer arm 100 using their respective threaded sections. This permits internal mechanical cleaning (wiping down the internal pathways, possibly by inserting a ramrod with an attached cleaning tool wetted by a cleaning solution) of each of the left upper arm 130L, right upper arm 130R, left elbow 140L, right elbow 140R, left lower arm 150L, right lower arm 150R, left shoulder 160L and right shoulder 160R.

While ends for each of the upper arms and lower arms may be threaded in the same direction, in a preferred embodiment, the ends for each upper arm 130 and lower arm 150 are threaded in the opposite direction. Thus, as a specific preferred example, one end of the right upper arm (or left upper arm, right lower arm or left lower arm) is threaded clockwise, while the other end of the right upper arm (or left upper arm, right lower arm or left lower arm) is threaded counterclockwise. This helps to keep the upper arms 130 and lower arms 150 from working loose from the wrist, upper elbow, lower elbow and shoulder threaded sections 200, 210, 220 and 230.

Bernoulli's principle may be used to securely retain a wafer on the hand 110, but requires a steady flow of gas through the transfer arm 100 to the hand 110. Interruptions in the flow of the gas by contaminates could cause the wafer to fall off the hand 110. To retain the wafer on the hand 110 a gas supplied by or to the automated wafer handling system must be able to sequentially pass through a shoulder gas conduit 240, a lower arm gas conduit 250, an elbow gas conduit 260, an upper arm gas conduit 270 and a hand gas conduit 280 before being expelled by gas ejection ports on the hand 110. The gas must not leak out (or the pressure will be reduced to the hand 110) of the transfer arm 100 regardless of the current position of the various parts of the transfer arm 100 or the twisting movements at the wrists 120, elbows 140 and shoulders 160.

As the transfer arm 100 is easily taken apart, the gas conduits are able to be easily cleaned, preventing blockages that might hinder the flow of the gas through the transfer arm 100. The disclosed transfer arm 100 may also reduce the leakage of any gas, further improving the reliability of the hand 110 to retain a wafer.

The transfer arm 100 may be attached to an automated wafer handling system. The automated wafer handling system may be able to impart on the transfer arm 100 any desired motions. As non-limiting examples, the automated wafer handling system may be able to raise and/or lower the transfer arm 100 in a substantially vertical direction and/or rotate the transfer arm 100 about a pivot point, where the pivot point is preferably located near or between the shoulders 160 of the transfer arm 100. The transfer arm 100 itself may be used to extend the hand 110 away from or towards the pivot point.

In operation, the automated wafer handling system may have a motor that rotates the shoulders 160 in opposite directions, i.e., the right shoulder may be rotated in a clockwise direction while the left shoulder may be rotated in counterclockwise direction or the right shoulder may be rotated in a counterclockwise direction while the left shoulder may be rotated in a clockwise direction to either extend or retract the hand 110, i.e., change the distance from the pivot point to the hand 110. The combinations of motions performed by the automated wafer handling system and the transfer arm 100 may allow the transfer arm 100 to move a wafer from a wafer cassette carrier to a processing station and then after processing from the processing station to the same or another wafer cassette carrier.

As an example embodiment of the invention, a transfer arm 100 may be configured to move a wafer inside a piece of equipment designed to manufacture computer chips. The transfer arm 100 may include a hand 110 which, in preferred embodiments, uses the Bernoulli's Principle to hold the wafer. A left wrist 120L and a right wrist 120R may be connected to the hand 110. The hand 110 and the left wrist 120L and the right wrist 120R may incorporate sealed gears and sealed bearings. A left upper arm 130L may be connected to the left wrist 120L and a right upper arm 130R may be connected to the right wrist 120R by a left wrist threaded section 200L and a right wrist threaded section 200R respectively. A left elbow 140L may be connected to the left upper arm 130L and a right elbow 140R may be connected to the right upper arm 130R by a left upper elbow threaded section 210L and a right upper elbow threaded section 210R respectively. A left lower arm 150L may be connected to the left elbow 140L and a right lower arm 150R may be connected to the right elbow 140R by a left lower elbow threaded section and a right lower elbow threaded section respectively. A left shoulder 160L may be connected to the left lower arm 150L and a right shoulder 160R may be connected to the right lower arm 150R by a left shoulder threaded section 230L and a right shoulder threaded section 230R respectively.

While the transfer arm 100 has been described using the names of biological body parts, e.g., wrists 120L and 120R, arms 130L, 130R, 150L and 150R, elbows 140R and 140L and shoulders 160L and 160R for ease of reference, it should be understood that the limitations of the biological body parts should not be imposed on the similarly named parts of the transfer arm 100.

The inventions and methods described herein can be viewed as a whole, or as a number of separate inventions, that can be used independently or mixed and matched as desired. All inventions, steps, processed, devices, and methods described herein can be mixed and matched as desired. All previously described features, functions, or inventions described herein or by reference may be mixed and matched as desired.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A transfer arm configured to move a wafer inside a piece of equipment designed to manufacture electronic circuits, comprising:
a hand;
a left wrist and a right wrist connected to the hand, wherein the hand and the left wrist and the right wrist comprise sealed gears and sealed bearings, and wherein the sealed gears are hidden from a line of sight of the wafer during a manufacturing process of the electronic circuits on the wafer;
a left upper arm connected to the left wrist and a right upper arm connected to the right wrist by a left wrist threaded section and a right wrist threaded section respectively;
a left elbow connected to the left upper arm and a right elbow connected to the right upper arm by a left upper elbow threaded section and a right upper elbow threaded section respectively;
a left lower arm connected to the left elbow and a right lower arm connected to the right elbow by a left lower elbow threaded section and a right lower elbow threaded section respectively; and
a left shoulder connected to the left lower arm and a right shoulder connected to the right lower arm by a left shoulder threaded section and a right shoulder threaded section respectively.

2. The transfer arm of claim 1, wherein a continuous airtight passage runs through the right shoulder, right lower arm, right elbow, right upper arm, right wrist and hand to permit the transfer arm to hold the wafer via Bernoulli's principle.

3. The transfer arm of claim 1, wherein a continuous airtight passage runs through the left shoulder, left lower arm, left elbow, left upper arm, left wrist and hand to permit the transfer arm to hold the wafer via the Bernoulli's principle.

4. The transfer arm of claim 1, wherein a continuous airtight passage runs through the right shoulder, right lower arm, right elbow, right upper arm, right wrist and hand and another continuous airtight passage runs through the left shoulder, left lower arm, left elbow, left upper arm, left wrist and hand to permit the transfer arm to hold the wafer via Bernoulli's principle.

5. The transfer arm of claim 1, wherein the wrist gears are in a closed compartment.

6. The transfer arm of claim 1, wherein the sealed bearings prevent gear wear particulates from transporting to the wafer during the manufacture of the electronic circuits.

7. The transfer arm of claim 1, wherein the sealed bearings contain any gear wear particulates within the sealed bearings.

8. The transfer arm of claim 1, wherein the wrist bearings are sealed from corrosive process gasses used to manufacture the electronic circuits.

9. The transfer arm of claim 1, wherein left wrist, right wrist, left upper arm, right upper arm, left elbow, right elbow, left lower arm, right lower arm, left shoulder and right shoulder are easily disconnected from each other and the transfer arm for easy internal cleaning.

10. A transfer arm configured to move a wafer inside a piece of equipment designed to manufacture electronic circuits, comprising:
a hand;
a left wrist and a right wrist connected to the hand, wherein the hand and the left wrist and the right wrist comprise sealed gears and sealed bearings, and wherein the sealed bearings are sealed from corrosive process gasses;
a left upper arm connected to the left wrist and a right upper arm connected to the right wrist by a left wrist threaded section and a right wrist threaded section respectively;
a left elbow connected to the left upper arm and a right elbow connected to the right upper arm by a left upper elbow threaded section and a right upper elbow threaded section respectively;
a left lower arm connected to the left elbow and a right lower arm connected to the right elbow by a left lower elbow threaded section and a right lower elbow threaded section respectively; and
a left shoulder connected to the left lower arm and a right shoulder connected to the right lower arm by a left shoulder threaded section and a right shoulder threaded section respectively.

11. The transfer arm of claim 10, wherein the wrist gears are in a closed compartment.

12. The transfer arm of claim 10, wherein the sealed gears are hidden from a line of sight of the wafer during the manufacture of the electronic circuits.

13. The transfer arm of claim 10, wherein the sealed bearings prevent gear wear particulates from transporting to the wafer during the manufacture process of the electronic circuits on the wafer.

14. The transfer arm of claim 10, wherein the sealed bearings contain any gear wear particulates within the sealed bearings.

15. The transfer arm of claim 10, wherein left wrist, right wrist, left upper arm, right upper arm, left elbow, right elbow, left lower arm, right lower arm, left shoulder and right shoulder are easily disconnected from each other and the transfer arm for easy internal cleaning.

16. A transfer arm configured to move a wafer inside a piece of equipment designed to manufacture electronic circuits, comprising:
a hand;
a left wrist and a right wrist connected to the hand, wherein the hand and the left wrist and the right wrist comprise sealed gears and sealed bearings;
a left upper arm connected to the left wrist and a right upper arm connected to the right wrist by a left wrist threaded section and a right wrist threaded section respectively;
a left elbow connected to the left upper arm and a right elbow connected to the right upper arm by a left upper elbow threaded section and a right upper elbow threaded section respectively;
a left lower arm connected to the left elbow and a right lower arm connected to the right elbow by a left lower elbow threaded section and a right lower elbow threaded section respectively;
a left shoulder connected to the left lower arm and a right shoulder connected to the right lower arm by a left shoulder threaded section and a right shoulder threaded section respectively; and
wherein the left upper arm, right upper arm, left elbow, right elbow, left lower arm, right lower arm, left shoulder and right shoulder are easily disconnected and removable from the transfer arm using their respective threaded sections to permit internal mechanical cleaning of each of the left upper arm, right upper arm, left elbow, right elbow, left lower arm, right lower arm, left shoulder and right shoulder.

17. The transfer arm of claim 16, wherein the wrist gears are in a closed compartment.

18. The transfer arm of claim 16, wherein the sealed gears are hidden from a line of sight of the wafer during a manufacturing process of the electronic circuits on the wafer.

19. The transfer arm of claim 16, wherein the sealed bearings prevent gear wear particulates from transporting to the wafer during the manufacture of the electronic circuits.

20. The transfer arm of claim 16, wherein the sealed bearings contain any gear wear particulates.
